(19) United States
(12) Patent Application Publication
(10) Pub. No.: US 2010/0245218 A1
(43) Pub. Date: Sep. 30, 2010

(54) LIGHT-EMITTING DEVICE AND DISPLAY DEVICE

(76) Inventors: Shogo Nasu, Hyogo (JP); Reiko Taniguchi, Osaka (JP); Eiichi Satoh, Osaka (JP); Takayuki Shimamura, Osaka (JP); Masayuki Ono, Osaka (JP); Masaru Odagiri, Hyogo (JP)

Correspondence Address: MCDERMOTT WILL & EMERY LLP, 600 13TH STREET, NW, WASHINGTON, DC, 20005-3096, US

(21) Appl. No.: 12/740,198

(22) PCT Filed: Oct. 31, 2008
(86) PCT No.: PCT/JP2008/003134

§ 371 Date: Apr. 28, 2010

(30) Foreign Application Priority Data
Nov. 1, 2007 (JP) 2007-285084
Feb. 5, 2008 (JP) 2008-025094

(51) Int. Cl. G09G 3/30; H01L 51/54

(52) U.S. Cl. 345/80; 257/13; 257/40; 977/773; 977/734; 977/742; 257/E51.026

(57) ABSTRACT

Disclosed is a light-emitting device including a first electrode and a second electrode arranged facing each other, at least one of the electrodes being transparent or semi-transparent, and a phosphor layer provided as being sandwiched between the first electrode and the second electrode. In the phosphor layer, conductive nano particles and phosphor particles are dispersed in a matrix including a hole-transporting material. Also disclosed is another light-emitting device including a first electrode and a second electrode arranged facing each other, at least one of the electrodes being transparent or semi-transparent, and a phosphor layer sandwiched between the first electrode and the second electrode. This phosphor layer includes a phosphor particle powder containing phosphor particles, the phosphor particle having at least surface covered with a coating layer, the coating layer including a hole transport material and conductive nano particles dispersed in the hole transport material.

### BACKGROUND

1. Technical Field

The present invention relates to a light-emitting device for electroluminescence and a display device using the light emitting device. This light emitting device is available as a variety of light sources for use in communication and illumination.

2. Description of the Related Art

In recent years, electroluminescence elements (hereinafter, referred to as EL elements) have attracted attention as light and thin surface-emitting elements. The EL elements are broadly divided into organic EL elements in which a direct-current voltage is applied to a fluorescent substance made of an organic material to recombine electrons and holes for light emission, and inorganic EL elements in which an alternating voltage is applied to a fluorescent substance made of an inorganic material to induce electrons accelerated in a high electric field of approximately 10⁶ V/cm to collide with the luminescent center of the inorganic fluorescent substance for excitation of the electrons, and permit the inorganic fluorescent substance to emit light in the relaxation process.

Further, the inorganic EL elements include dispersion EL elements in which inorganic fluorescent substance particles are dispersed in a binder made of a polymer organic material to serve as a phosphor layer, and thin-film EL elements in which an insulating layer is provided on one or both sides of a thin-film phosphor layer with a thickness on the order of 1 μm. Among these elements, the dispersion EL elements have attracted attention because of the advantages of their lower power consumption and even lower manufacturing cost due to their simpler manufacturing processes.

The EL element referred to as a dispersion EL element will be described. Conventional EL elements have a layered structure including a substrate, a first electrode, a phosphor layer, an insulator layer, and a second electrode in order from the substrate side. The phosphor layer includes inorganic fluorescent substance particles such as ZnS:Mn dispersed in an organic binder, and the insulator layer includes a strong insulator such as BaTiO₃ dispersed in an organic binder. An alternating-current power supply is placed between the first electrode and the second electrode, and a voltage is applied from the alternating-current power supply to the first electrode and the second electrode to permit the EL element to emit light.

In the structure of the dispersion EL element, the phosphor layer is a layer which determines the luminance and efficiency of the dispersion EL element, and particles with a size of 15 μm to 35 μm in particle diameter is used for the inorganic fluorescent substance particles of this phosphor layer. Furthermore, the luminescent color of the phosphor layer of the dispersion EL element is determined by the inorganic fluorescent substance particles used in the phosphor layer. For example, orange light emission is exhibited in the case of using ZnS:Mn for the inorganic fluorescent substance particles, and for example, blue-green light emission is exhibited in the case of using ZnS:Cu for the inorganic fluorescent substance particles. As described above, the luminescent color is determined by the inorganic fluorescent substance particles. Thus, when light of other, white luminescent color is to be emitted, an organic dye is mixed into the organic binder to convert the luminescent color, thereby obtaining the intended luminescent color.

However, light emitters for use in the EL elements have the problems of low light emission luminance and short lifetime.

As a method for increasing the light emission luminance, a method of increasing the voltage applied to the phosphor layer is conceivable. In this case, there is a problem that the half-life of the light output from the light emitter is decreased in proportion to the applied voltage. On the other hand, as a method for making the half-life longer, that is, making the lifetime longer, a method of decreasing the voltage applied to the phosphor layer is conceivable. However, this method has the problem of decrease in light emission luminance. As described above, the light emission luminance and the half-life have a relationship in which when the voltage applied to the phosphor layer is increased or decreased to try to improve one of the light emission luminance and the half-life, the other will be degraded. Therefore, one will have to select either the light emission or the half-life. It is to be noted that the half-time in the specification refers to a period of time until the light output from the light emitter is decreased to the half output of the original luminance.

Thus, suggestions have been made for driving light emitting devices with low voltages, as described in Japanese Patent Laid-Open Publication No. 2006-120328 and Japanese Patent Laid-Open Publication No. 2006-127780. According to this suggestion, in a dispersion EL element, a phosphor layer and a dielectric are interposed between a transparent electrode and a rear electrode, and the phosphor layer has an acicular substance with its conductivity higher than that of a fluorescent substance with being dispersed in an organic binder. Since the acicular substance is dispersed, high-energy electrons are permitted to collide efficiently with the fluorescent substance, thereby allowing for a longer lifetime and a higher efficiency.

### SUMMARY

However, in the above proposal, it is essential to provide the dielectric layer for constituting dispersion EL, and it is further necessary to apply a high alternating voltage between the electrodes for permitting the phosphor layer to emit light. As a result, the dispersion type EL has a problem that it is hard to obtain long lifetimes and high efficiencies.

An object of the present invention is to solve the problem described above and to provide a light emitting device which is driven at a low voltage, exhibits a high light emission luminance, and has a long lifetime.

A light-emitting device according to the present invention includes:

a first electrode and a second electrode arranged facing each other, at least one of the electrodes being transparent or semi-transparent; and

a phosphor layer provided as being sandwiched between the first electrode and the second electrode, wherein conductive nano particles and phosphor particles are dispersed in a matrix including a hole-transporting material.

A light-emitting device according to the present invention includes:

a first electrode and a second electrode arranged facing each other, at least one of the electrodes being transparent or semi-transparent; and

a phosphor layer sandwiched between the first electrode and the second electrode, the phosphor layer including a phosphor particle powder containing phosphor particles, the phosphor particle having at least surface covered with a coating layer, the coating layer including a hole transport material and conductive nano particles dispersed in the hole transport material.

The phosphor layer may include binder among the phosphor particles.

The conductive nano particles may be interspersed among the respective phosphor particles, the respective phosphor particles may form an electrical connection through the conductive nano particles.

The conductive nano particles may include at least one metal fine particle selected from the group constituting of Ag, Au, Pt, Ni, and Cu. Further, the conductive nano particles may include at least one oxide fine particle selected from the group constituting of an indium tin oxide, ZnO, and InZnO. The conductive nano particles may include at least one carbon substance fine particle selected from the group of fullerene and a carbon nanotube.

The conductive nano particles may have an average particle diameter within the range of 1 to 200 nm.

The hole transport material may include an organic hole transport material including an organic matter.

The organic hole transport material may contain components of the following chemical formula 1 and chemical formula 2.

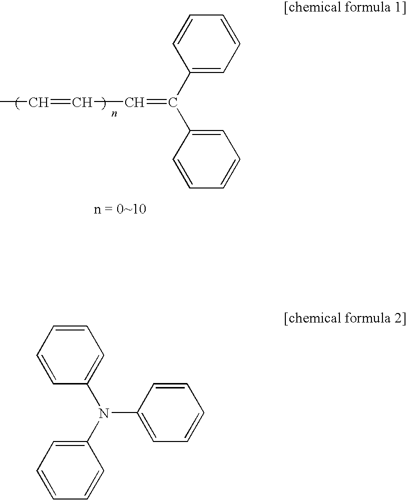

The organic hole transport material may further include at least one component of the group constituting of the following chemical formula 3, chemical formula 4, and chemical formula 5.

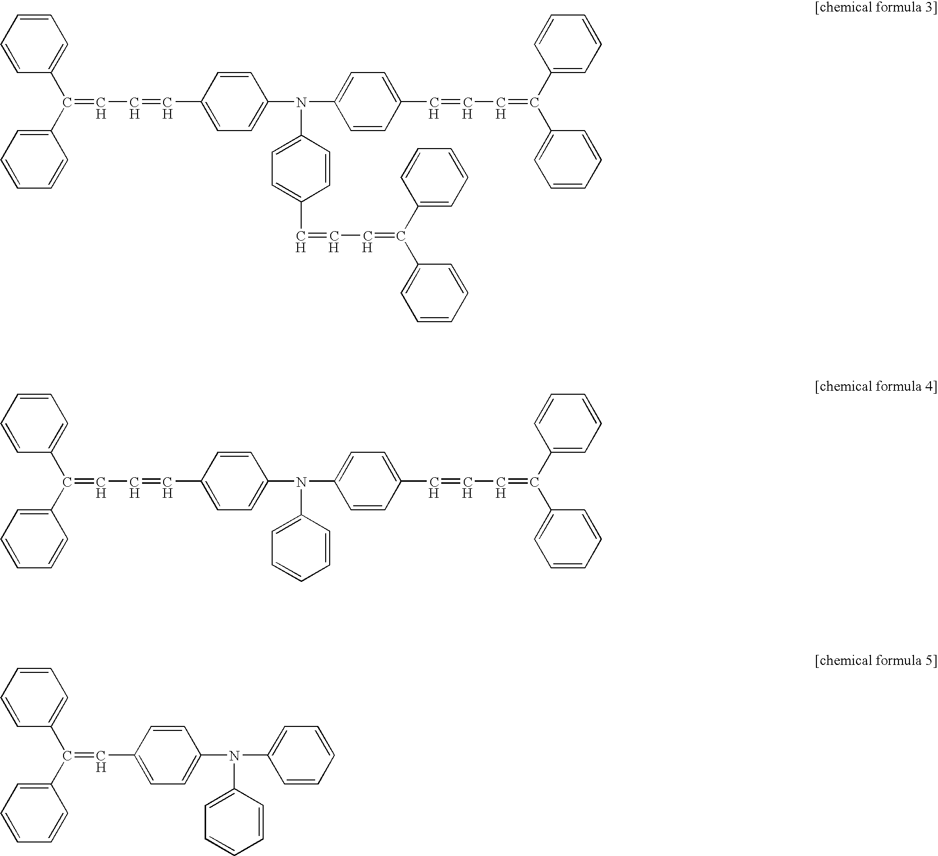

The organic hole transport material may further include at least one component of the group constituting of the following chemical formula 6, chemical formula 7, and chemical formula 8.

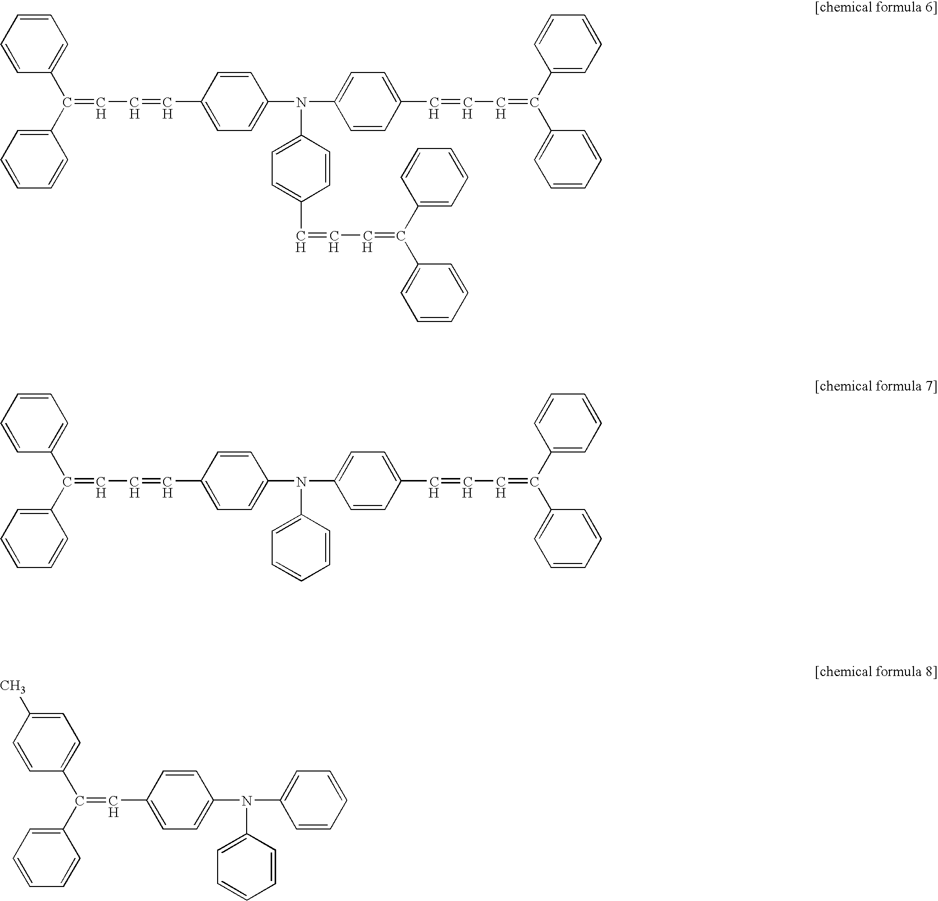

The hole transport material may include an inorganic hole transport material including an inorganic matter.

The phosphor particles may include a particle including a Group 13-Group 15 compound semiconductor. The phosphor particles may include at least one light emitting material selected from the group of a nitride, a sulfide, a selenide, and an oxide. The phosphor particles are nitride semiconductor particles may include at least one element of Ga, Al, and In. The phosphor particles may be phosphor particles including GaN.

The phosphor particles may have an average particle diameter within the range of 0.1 μm to 1000 μm.

The conductive nano particles may be selected from the group of metal material particles such as Ag, Au, Pt, Ni, and Cu. The conductive nano particles may be selected from oxide particles such as an indium tin oxide, ZnO, and InZnO. The conductive nano particles may be selected from the group of carbon material particles such as a carbon nanotube.

The conductive nano particles may have an average particle diameter or an average length within the range of 1 to 200 nm.

The light emitting device of the present invention may further include a hole injection layer sandwiched between the first electrode and the phosphor layer. The light emitting of the present invention may further include a support substrate facing the first electrode or the second electrode for support. The support substrate may be a glass substrate or a resin substrate.

The light emitting device of the present invention may further include a thin film transistors connected to the first electrode or the second electrode.

A display device according to the present invention includes:

a light emitting device array in which the light emitting device is two-dimensionally arranged in plural;

a plurality of x electrodes extending parallel to each other in a first direction parallel to a surface of the light emitting device array; and

a plurality of y electrodes extending parallel to a second direction parallel to the surface of the light emitting device array and orthogonal to the first direction,

wherein the thin film transistors of the light emitting device array are each connected to the x electrodes and the y electrodes.

A display device according to the present invention includes:

a light emitting device array in which the light emitting device is two-dimensionally arranged in plural;

a plurality of x electrodes extending parallel to each other in a first direction parallel to a surface of the light emitting device array; and

a plurality of y electrodes extending parallel to a second direction parallel to the surface of the light emitting device array and orthogonal to the first direction.

The display device according to the present invention may further include a color conversion layer anteriorly in a direction of light emission extraction.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a cross-sectional view perpendicular to a light emitting surface of a light emitting device according to first embodiment of the present invention;

FIG. 2 is a cross-sectional view perpendicular to a light emitting surface of a modification example of the light emitting device according to first embodiment of the present invention;

FIG. 3 is a cross-sectional view perpendicular to a light emitting surface of a modification example of the light emitting device according to first embodiment of the present invention;

FIG. 4 is a graph showing the relationship between the applied voltage and luminance of a light emitting device according to an example of the present invention;

FIG. 5 is a cross-sectional view perpendicular to a light emitting surface of a light emitting device according to second embodiment of the present invention;

FIGS. 6A and 6B are cross-sectional view illustrating the schematic structures of light emitting composite particles for use in the light emitting device according to second embodiment of the present invention;

FIG. 7 is a cross-sectional view perpendicular to a light emitting surface of a modification example of the light emitting device according to second embodiment of the present invention;

FIG. 8 is a cross-sectional view perpendicular to a light emitting surface of a modification example of the light emitting device according to second embodiment of the present invention;

FIG. 9 is a schematic perspective view of a light emitting device according to third embodiment of the present invention;

FIG. 10 is a schematic perspective view of a display device according to fourth embodiment of the present invention;

FIG. 11 is a schematic perspective view of a display device according to fifth embodiment of the present invention; and

FIG. 12 is a cross-sectional view perpendicular to a light emitting surface of a light emitting device according to sixth embodiment of the present invention.

### DESCRIPTION OF THE PREFERRED EMBODIMENTS

Light emitting devices according to embodiments of the present invention will be described below with reference to the accompanying drawings. It is to be noted that the practically same members are denoted by the same reference numerals in the drawings.

### First Embodiment

### Schematic Structure of EL Element

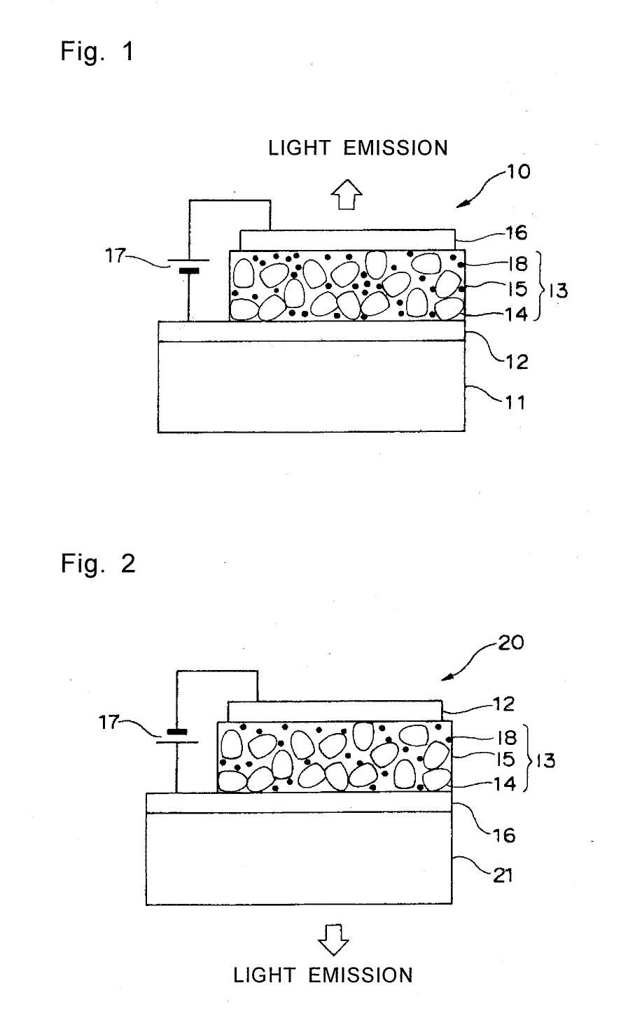

FIG. 1 is a schematic cross-sectional view illustrating the structure of a light emitting device according to preset embodiment. This light emitting device 10 includes a rear electrode 12 that is a first electrode, a transparent electrode 16 that is a second electrode, and a phosphor layer 13 sandwiched between the pair of electrodes 12, 16. The phosphor layer 13 includes phosphor particles 14 and conductive nano particles 18 dispersed in a hole transport material 15 including an organic matter as a matrix. Furthermore, a direct-current power supply 17 is connected between the rear electrode 12 that is the first electrode and the transparent electrode 16 that is the second electrode to apply a voltage. When power is supplied between the electrodes 12, 16, a potential difference is produced between the rear electrode 12 and the transparent electrode 16, thereby applying a voltage. Then, holes and electrons as carriers are injected from the rear electrode 12 and the transparent electrode 16 through the conductive nano particles 18 and the hole transport material 15 into the phosphor particles 14, and recombined to emit light. The emitted light is extracted from the transparent electrode 16 side to the outside.

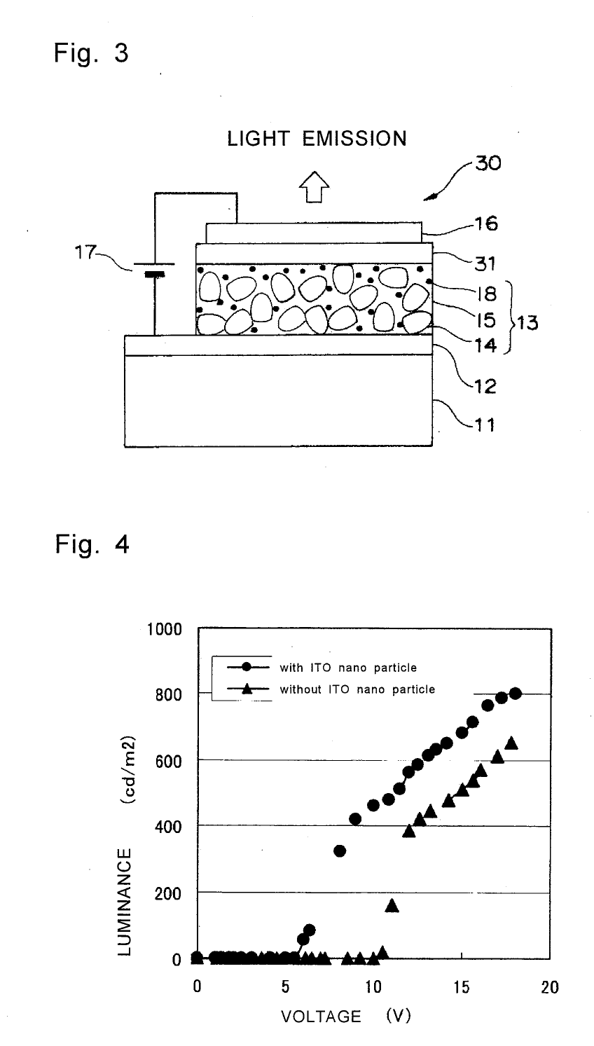

It is to be noted that the present invention is not limited to the structure described above, and changes can be appropriately made, in such a way that the rear electrode 12 and the transparent electrode 16 are interchanged, transparent electrodes are used for both of the electrode 12 and the electrode 16, or an alternating-current power supply is used as the power supply. Furthermore, changes can be appropriately made, in such a way that a black electrode is used as the rear electrode 12, or a structure is further provided for sealing all or part of the light element 10 with a resin or a ceramic. Furthermore, a modification example as shown in FIG. 2 is also possible. A light emitting device 20 shown in FIG. 2 is different as compared with the light emitting device 10 shown in FIG. 1, in that the electrodes are reversed in terms of polarity and arrangement. Light emitted from the phosphor layer 13 is extracted through transparent electrode 16 and a transparent substrate 11 toward the outside of the element. Furthermore, a modification example as shown in FIG. 3 is also possible. A light emitting device 30 shown in FIG. 3 is different as compared with the light emitting device 10 shown in FIG. 1, in that a hole injection layer 31 is further provided between a transparent electrode 16 and a phosphor layer 13. This lowers the driving voltage of the light emitting device 30, and improves the stability in hole injection from the electrode.

The respective components of the light emitting device will be described below in detail with reference to FIGS. 1 to 3.

### <Substrate>

In FIG. 1, for the substrate 11, a substrate can be used to support respective layers formed on the substrate. Specifically, silicon, ceramics such as Al₂O₃ and AlN, and the like can be used. Furthermore, plastic substrates such as a polyester and a polyimide may be used. In addition, when light is extracted from the side of the substrate 11, the substrate 11 is required to be a light transmitting material with respect to the wavelength of light emitted from a light emitter. As such a material, for example, glass such as Corning 1737, quartz, and the like can be used. In order to prevent alkali ions and the like contained in normal glass from having an effect on the light emitting device, the material may be non-alkali glass, or soda lime glass with a glass surface coated with alumina or the like as an ion barrier layer. These are examples, and the material of the substrate 11 is not considered limited to these examples.

Alternatively, when no light is extracted from the substrate side, the light transmitting property described above is not required, and materials without any light transmitting property can also be used.

### <Electrode>

The electrodes include the rear electrode 12 and the transparent electrode 16. Of the two electrodes, the electrode on the side from which light is extracted is used as the transparent electrode 16. On the other hand, the other is used as the rear electrode 12.

To the rear electrode 12 on the side from which no light is extracted, any well-known conductive material may be applied as a rear electrode. For example, a thin film metal such as Au, Ag, Al, Cu, Ta, Ti, or Pt, or a laminate of one or more of the metals can be used.

The material of the transparent electrode 16 on the side from which light is extracted may be any material having a light transmitting property, and the material preferably has a low resistance. Materials which are particularly preferred as the material of the transparent electrode 16 include, but are not particularly limited to, metal oxides based on an ITO (In₂O₃ doped with SnO₂, which is also referred to as an indium tin oxide), ZnO, ALZnO, GaZnO, or the like; or conductive polymers such as a polyaniline, a polypyrrole, PEDOT/PSS, and a polythiophene.

An ITO can be deposited by a deposition method such as sputtering, electron beam evaporation, or ion plating, for the purpose of improving the transparency or lowering the resistivity. Furthermore, after the deposition, surface treatment such as a plasma treatment may be applied for the purpose of controlling the resistivity. The film thickness of the transparent electrode is determined from the required sheet resistance and visible light transmittance. While the transparent electrode 16 may be directly formed on the phosphor layer 13, a transparent conductive film may be formed on a glass substrate and attached so that the transparent conductive film comes in contact with the phosphor layer 13.

It is to be noted that the rear electrode 12 may be configured to cover the entire surface of the layer, or may be configured to have a plurality of stripe-shaped electrodes in the layer. Furthermore, the rear electrode 12 and the transparent electrode 16 may be configured to have a plurality of stripe-shaped electrodes, in such a way that each stripe-shaped electrode of the rear electrode 12 and all of the strip-shaped electrodes of the transparent electrode 16 have a skew relationship with each other and that projections of each stripe-shaped electrode of the rear electrode 12 onto the light emitting surface and projections of all of the stripe-shaped electrodes of the rear electrode 16 onto the light emitting surface intersect with each other. In this case, the application of a voltage to the electrodes selected respectively from the respective stripe-shaped electrodes of the rear electrode 12 and the respective striped-shaped electrodes of the transparent electrode 16 allows a display to be configured in such a way that light is emitted in a predetermined position.

### <Phosphor Layer>

The phosphor layer 13 is configured in such a way that the phosphor particles 14 and conductive nano particles 18 are each dispersed in the hole transport material 15 as a matrix (FIGS. 1, 2, and 3). It is to be noted that the phosphor layer 13 is not limited to this example, and may include phosphor particle powder containing light emitting composite particles 50 (FIG. 6A) with the surface of each of phosphor particles 14 covered with a hole transport material 15 with conductive nano particles 18 dispersed therein, or include phosphor particle powder containing light emitting composite particles 50 (FIG. 6B) with at least a portion of the surface of each of phosphor particles 14 coated with a hole transport material 15 with conductive nano particles 18 dispersed therein.

### <Hole Transport Material>

Next, the hole transport material 15 will be described, which covers the surface of each of the phosphor particles 14 or serves as a matrix material existing among the phosphor particles 14. Any organic material having the function of generating and transporting holes can be used for the hole transport material 15. In addition, as the hole transport material 15, organic hole transport materials and inorganic hole transport materials are cited. The hole transport material 15 is preferably a material with a high hole mobility.

### <Organic Hole Transport Material>

This organic hole transport material preferably contains components of the following chemical formula 9 and chemical formula 10.

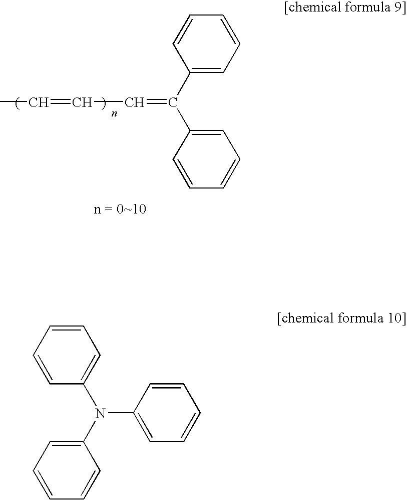

It is believed that the advantageous effect of the organic hole transport material containing the components of the above chemical formula 9 and chemical formula 10 is efficient injection of holes for the phosphor particles 14.

Furthermore, this organic hole transport material may contain any of the following chemical formula 11, chemical formula 12, and chemical formula 13 as a component.

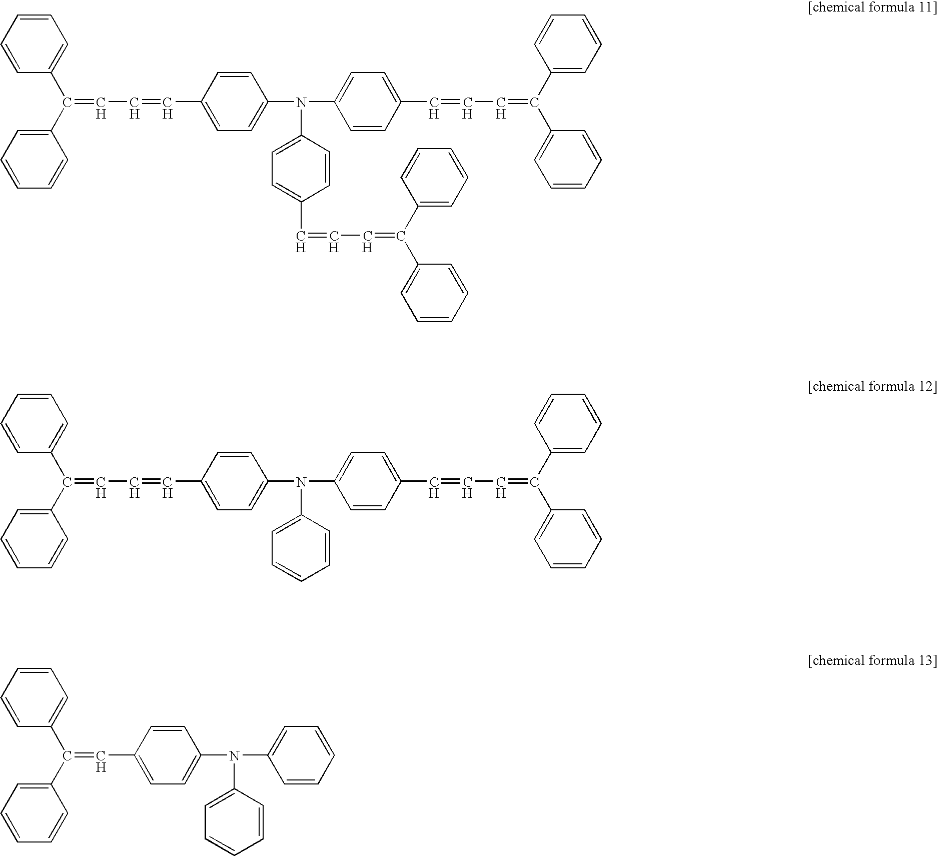

In addition, the main types of organic hole transport materials are low-molecular-weight materials and high-molecular-weight materials. Low-molecular-weight materials having a hole transport property include diamine derivatives used by Tang et al., such as N,N′-bis(3-methylphenyl)-N,N′-diphenylbenzidine (TPD) and N,N′-bis(a-naphthyl)-N,N′-diphenylbenzidine (NPD), in particular, diamine derivatives having a Q1-G-Q2 structure, disclosed in Japanese Patent No. 2037475, where Q1 and Q2 are separately a group having a nitrogen atom and at least three carbon chains (at least one of the carbon chains comes from an aromatic group), and G is a linking group including a cycloalkylene group, an arylene group, an alkylene group or a carbon-carbon bond. Alternatively, the organic hole transport material may be polymers (oligomers) including these structural units. These polymers include polymers having a Spiro structure or a dendrimer structure. Furthermore, the form in which molecules of a low-molecular-weight hole transport material are dispersed in a nonconductive polymer is likewise available. Specific examples of the molecular dispersion system include an example in which molecules of TPD are dispersed in high concentration in a polycarbonate, with the hole mobility on the order of 10⁻⁴ to 10⁻⁵ cm²/Vs.

Moreover, other examples of the hole transport material include tetraphenyl butadiene materials, hydrazine materials such as 4-(bis(4-methylphenyl)amino)benzaldehyde diphenylhydrazine, stilbene materials such as 4-methoxy-4′-(2,2′-diphenylvinyl)triphenylamines, PEDOT (poly(2,3-dihydrocyano-1,4-dioxin)), α-NPD, DNTPD, and a Cu phthalocyanine.

On the other hand, high-molecular-weight materials having a hole transport property include π-conjugated polymers and σ-conjugated polymers, and for example, a high-molecular-weight material in which an arylamine compound is incorporated. Specifically, the high-molecular-weight materials include, but are not limited to, poly-para-phenylenevinylene derivatives (PPV derivatives), polythiophenes derivatives (PAT derivatives), polyparaphenylene derivatives (PPP derivatives), polyalkylphenylene (PDAF), polyacetylene derivatives (PA derivatives), and polysilane derivatives (PS derivatives). Furthermore, the high-molecular-weight materials may be polymers with a low-molecular-weight hole-transport molecular structure incorporated into their molecular chains, and specific examples of the polymers include polymethacrylamides with an aromatic amine in their side chains (PTPAMMA, PTPDMA) and polyethers with an aromatic amine in their main chains (TPDPES, TPDPEK). Above all, as a particularly preferred example, above all, poly-N-vinylcarbazole (PVK) exhibits an extremely high hole mobility of 10⁻⁶ cm²/Vs. Other specific examples include PEDOT/PSS and polymethylphenylsilane (PMPS).

Moreover, more than one type of the hole transport materials mentioned above may be mixed and used. Furthermore, the organic hole transport material may contain a crosslinkable or polymerizable material cross-linked or polymerized by light or heat.

### <Inorganic Hole Transport Material>

Inorganic hole transport materials will be described. The inorganic hole transport material may be any material being transparent or semi-transparent and having p-type conductivity. Preferred inorganic hole transport materials include metalloid semiconductors such as Si, Ge, SiC, Se, SeTe, and As₂Se₃; binary compound semiconductor such as ZnSe, CdS, ZnO, and CuI; chalcopyrite semiconductors such as CuGaS₂, CuGaSe₂, and CuInSe₂, and further mixed crystals of these semiconductors; and oxide semiconductors such as CuAlO₂ and CuGaO₂, and further mixed crystals of these semiconductors. Moreover, a dopant may be added to these materials, in order to control the conductivity.

### <Phosphor Particles>

As the phosphor particles 14, any material having an optical bandgap being as wide as visible light can be used. Specifically, with a nitride such as GaN, InGaN, or AlGaN, ZnSe or ZnS, or further ZnS, ZnSe, GaP, CdSe, CdTe, SrS, CaS, or ZnO as a mother body, the mother body can be used as it is, or phosphor particles with the addition of one or more elements selected from Ag, Al, Ga, Cu, Mn, Cl, Tb, Li, Zn, O, and Si can be used. In addition, multicomponent compounds such as ZnSSe and thiogallate based phosphor can be also used.

### <Conductive Nano Particles>

The conductive nano particles 18 used for the light emitting devices according to the present invention can use metal material particles such as Ag, Au, Pt, Ni, and Cu, oxide particles such as an indium tin oxide, ZnO, and InZnO, carbon material particles such as carbon nanotubes. The average particle diameter or average length of the conductive nano particles 18 preferably falls within the range of 1 nm to 200 nm. The average particle diameter or average length less than 1 nm results in poor conductivity, decreasing the light emission luminance. On the other hand, the average particle diameter or average length greater than 200 nm increases electrical conduction between the electrodes, while the number of the phosphor particles 14 which are not included in the conductive path is increased, decreasing the light emission luminance and efficiency.

The production of carbon nanotubes is carried out by a method such as a vapor phase synthetic method or plasma method, and depending on the manufacturing conditions, the electrical characteristics, diameters, lengths, and the like of the carbon nanotubes can be arbitrarily varied. As the phosphor particles 14 covered with the hole transmit material 15, p-type carbon nanotubes may be used. The p-type carbon nanotubes are obtained by adding an element such as K or Cs as a dopant to carbon nanotubes.

### Example 1

As an example of the present invention, a method for obtaining the phosphor layer 13 by an application method will be described. As an example, a light emitting device 10 was manufactured as shown in FIG. 1.

(a) A silicon substrate 11 with a Pt electrode formed was used as a substrate.

(b) Next, with the use of ITO nano particles with an average particle diameter of 20 to 30 nm as the conductive nano particles 17, the ITO nano particles were added at 10 weight % to a resin paste, and well mixed and dispersed.

(c) Next, as the hole transport material 15, tetraphenylbutadiene T770 dissolved in a resin solution was used. GaN particles with an average particle diameter of 500 to 1000 nm were, as the phosphor particles 14, mixed into the solution, coated and dried, and then mixed into the resin paste with the ITO nano particles 17 dispersed therein to obtain a light emitting paste.

(d) Next, the light emitting paste was applied on a glass substrate with an ITO film deposited thereon. The thickness of the applied film was about 30 μm.

(d) Furthermore, a substrate obtained by depositing an ITO as a transparent conductive film on glass by sputtering was attached to bring the ITO surface into contact with the phosphor layer 13. It is to be noted that the film thickness of the ITO film was about 300 nm.

The light emitting device was obtained in the way described above.

The evaluation of the prepared light emitting device was carried out by applying a direct-current voltage from the power supply 17 between the rear electrode 12 and the transparent electrode 16. Furthermore, the luminance measurement was carried out with the use of a portable luminance meter. It is to be noted that a light emitting device was prepared as a reference without the use of conductive nano particles 18.

FIG. 4 is a graph showing the relationship between the applied voltage and the luminance for light emitting devices according to the example of the present invention and the reference example. It is determined from FIG. 4 that when the ITO nano particles as the conductive nano particles 18 are dispersed in the hole transport material 15 as in the example, the voltage at which light emission is started is lower with a higher luminance, as compared with the case without the use of conductive nano particles as in the reference example. The results show that orange light is started to be emitted at a direct-current voltage of 5 V and produced a light emission luminance of about 800 cd/m² at 18 V.

It is to be noted that while the positive voltage and the negative voltage were applied respectively to the rear electrode 12 and the transparent electrode 16 in the present example, the light emitting device was allowed to emit light likewise even when the polarity was changed.

### <Advantageous Effects>

The light emitting device according to the present embodiment operates at a lower voltage than conventional light emitting devices, and is thus excellent in corrosion resistance and oxidation resistance and can provide a higher luminance and a longer lifetime than conventional light emitting devices.

### Second Embodiment

### Schematic Structure of Light Emitting Device

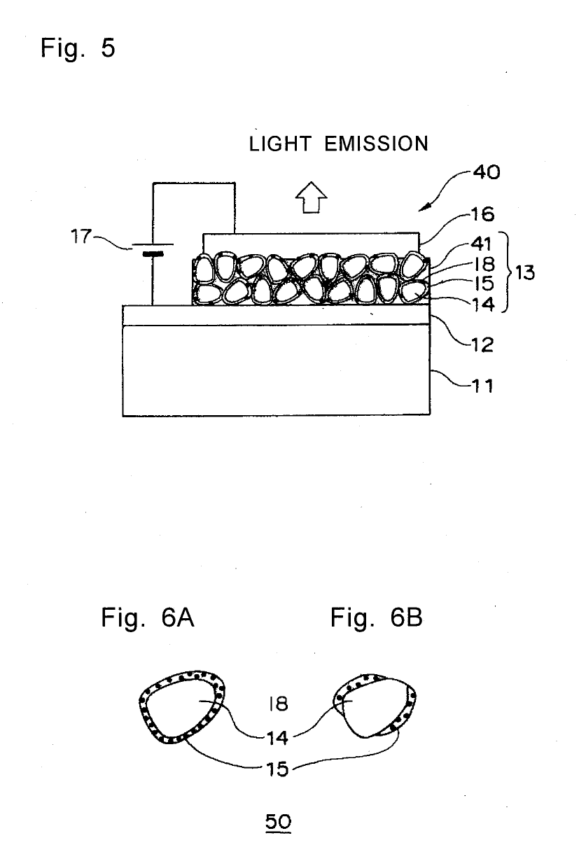

A light emitting device according to second embodiment of the present invention will be described with reference to FIGS. 5 and 6. FIG. 5 is a cross-sectional view perpendicular to a light emitting surface, illustrating the schematic structure of a light emitting device 40 according to second embodiment. The light emitting device 40 is different as compared with the light emitting device 10 shown in FIG. 1, in that the phosphor layer 13 includes phosphor particle powder including light emitting composite particles 50 shown in FIG. 6A or FIG. 6B. FIG. 6A is a cross sectional view illustrating a cross section structure of a light emitting composite particle 50 with the entire surface of a phosphor particle 14 coated with a hole transport material 15 with conductive nano particles 18 dispersed therein, whereas FIG. 6B is a cross sectional view illustrating a cross section structure of a light emitting composite particle 50 with at least a portion of the surface of a phosphor particle 14 coated with a hole transport material 15 with conductive nano particles 18 dispersed therein. The coated layer of the hole transport material has a thickness in the range of 1 μm to 10 μm, preferably in the range of 2 μm to 3 μm. Furthermore, this light emitting device is different as compared with the light emitting device according to the first embodiment, in that the light emitting composite particles 50 described above are arranged between the rear electrode 12 and the transparent electrode 16 with an organic binder 41 as a binding agent. The light emitting device 40 according to the second embodiment is characterized in that the conductive nano particles held on the surface of each of the phosphor particles 14 and coated thereon with the organic hole transport material 15, as well as some of the conductive nano particles 18 exposed improve the hole injection property, and also improve the electron injection property.

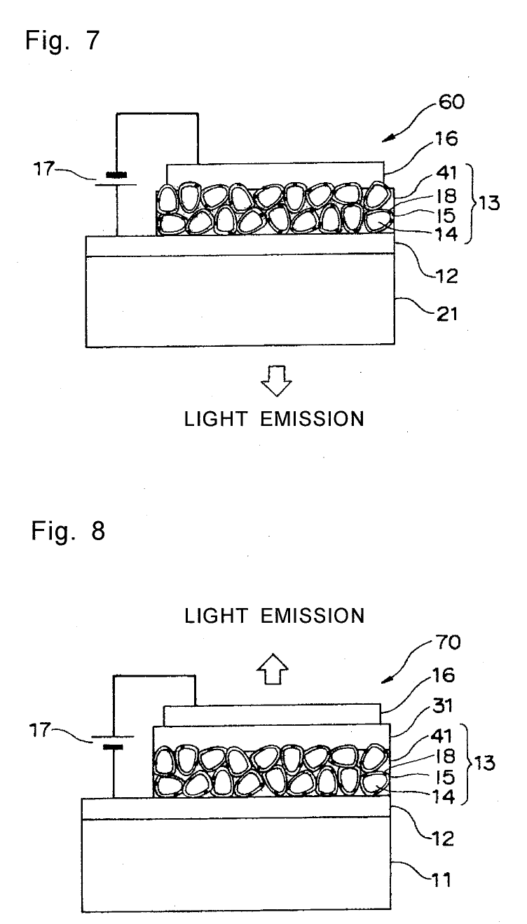

It is to be noted that the embodiment is not limited to the structure described above, changes can be appropriately made, in such a way that a black electrode is used as the rear electrode 12, or a structure is further provided for sealing all or part of the light element 40 with a resin or a ceramic. Furthermore, a modification example as shown in FIG. 7 is also possible. A light emitting device 60 shown in FIG. 7 is different as compared with the light emitting device 40 shown in FIG. 5, in that the electrodes are reversed in terms of polarity and arrangement. Light emitted from the phosphor layer 13 is extracted through a transparent electrode 16 and a transparent substrate 21 toward the outside of the element. Furthermore, a modification example as shown in FIG. 8 is also possible. A light emitting device 70 shown in FIG. 8 is different as compared with the light emitting device 40 shown in FIG. 5, in that a hole injection layer 31 is further provided between a transparent electrode 16 and a phosphor layer 13. This lowers the driving voltage of the light emitting device 70, and improves the stability in hole injection from the electrode.

### <Advantageous Effects>

The light emitting device according to the present embodiment is able to form a planar shape with relative ease, and can achieve a light emitting device with a high luminance, a high efficiency, and high reliability.

### Third Embodiment

### Schematic Structure of Light Emitting Device

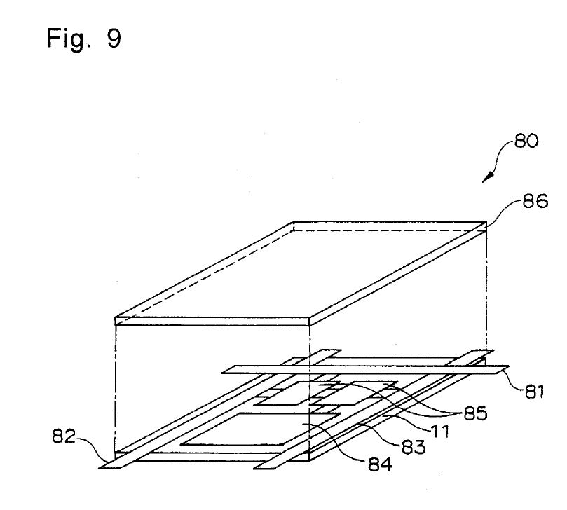

A light emitting device according to third embodiment of the present invention will be described with reference to FIG. 9. FIG. 9 is a perspective view illustrating the electrode composition of the light emitting device 80. This light emitting device 80 further includes thin film transistors (hereinafter, abbreviated as TFTs, and including two TFTs of a switching TFT and a driving TFT in FIG. 9) 85 connected to the pixel electrodes 84. The TFTs 85 are connected to a scan line 81, a data line 82, and a current supply line 83. In this light emitting device 80, since light emission is extracted from the side of a transparent common electrode 86, the aperture ratio can be adjusted higher regardless of the arrangement of the TFTs 85 on a substrate 11. Furthermore, the use of the TFTs 85 allows the light emitting device 80 to have a memory function. As the TFTs 85, low temperature polysilicon TFTs, amorphous silicon TFTs, organic TFTs including organic materials such as pentacene can be used. Moreover, the TFTs 85 may be inorganic TFTs composed of ZnO, InGaZnO₄, etc.

### Fourth Embodiment

### Schematic Structure of Display Device

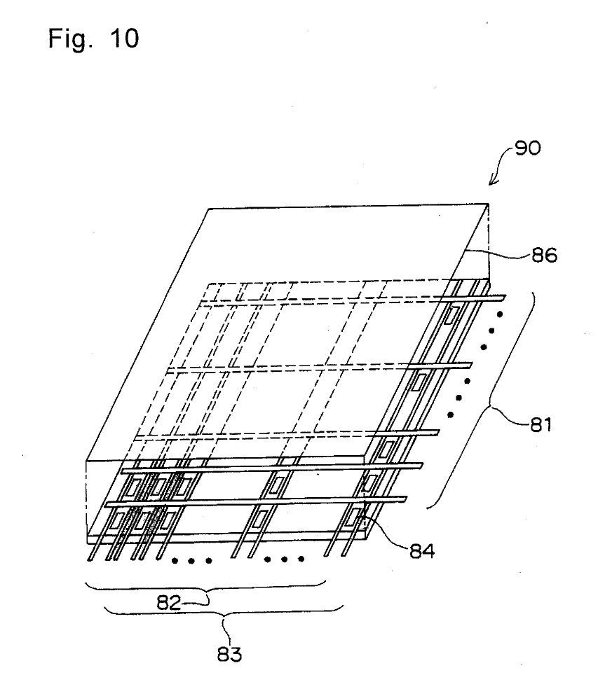

FIG. 10 is a schematic plan view illustrating the configuration of an active matrix display device 90 according to fourth embodiment of the present invention. This display device 90 includes pixel electrodes 84, a common electrode 86, scan limes 81, data lines 82, current supply lines 83, and TFTs (omitted in the figure). This display device 90 further includes a light emitting device array in which the light emitting device shown in FIG. 9 is two-dimensionally arranged in plural, a plurality of scan lines 81 extending parallel to each other in a first direction parallel to the surface of the light emitting device array, a plurality of data lines 82 extending parallel to a second direction parallel to the surface of the light emitting device array and orthogonal to the first direction, and a plurality current supply lines 83 extending parallel to the second direction. The TFTs on this light emitting device array are electrically connected to the scan lines 81, the data lines 82, and the current supply lines 83. The light emitting device specified by a pair of scan line 81 and data line 82 serves as one pixel. Furthermore, in this active matrix display device 90, a current is supplied from the current supply line 83 through the TFT to one pixel selected by the scan line and the data line to drive the selected light emitting device, and the obtained light emission is extracted from the side of the transparent common electrode 86.

Furthermore, in the case of a color display device, the phosphor layers may be deposited separately with the use of phosphor particles for each color of RGB. Alternatively, light emitting units such as electrode/phosphor layer/electrode may be laminated for each of RGB. Moreover, in the case of another color display device, after preparing a display device with phosphor layers for a single color or two colors, color filters and/or color conversion filters can be used to display each color of RGB. For example, RGB display is made possible by providing blue phosphor layers further with filters each for color conversion from a blue color to a green color or from a blue color or a green color to a red color.

### <Advantageous Effects>

In this active matrix display device 90, the phosphor layer 13 constituting the light emitting device of each pixel includes, as described above, the phosphor particles 14 and conductive nano particles 18 dispersed in the organic hole transport material 15 as a matrix, or includes light emitting powder containing the phosphor particles 14 with their surfaces coated with the organic hole transport material 15 with the conductive nano particles 18 dispersed therein. This allows a display device with a high light emission luminance, a high luminous efficiency, and high reliability to be achieved.

### Fifth Embodiment

### Schematic Structure of Display Device

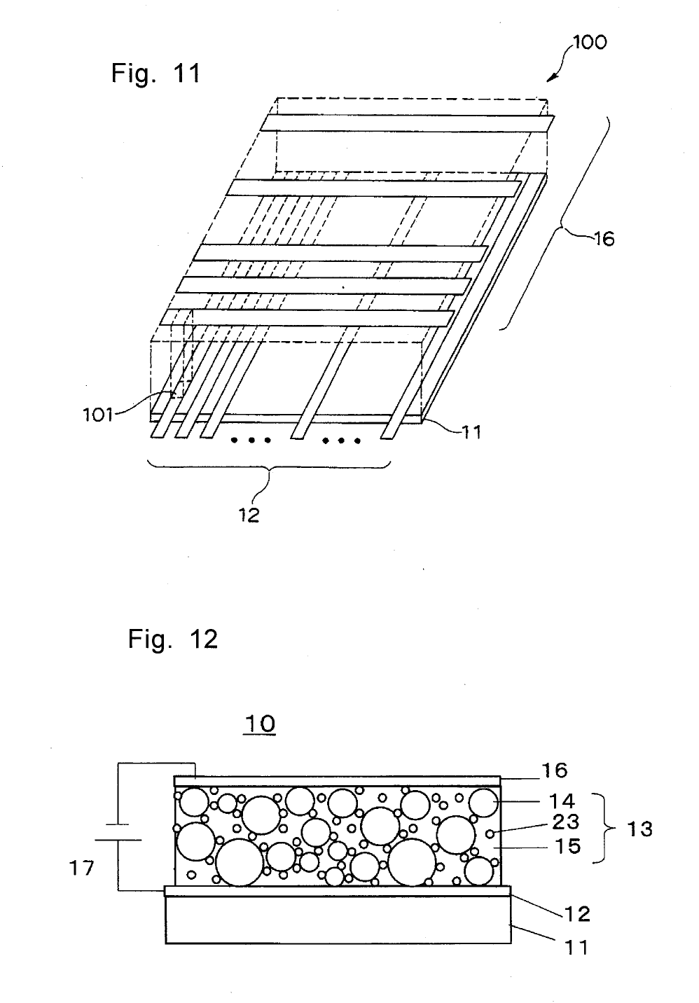

A display device according to fifth embodiment of the present invention will be described with reference to FIG. 11. FIG. 11 is a schematic plan view illustrating a passive matrix display device 100 including rear electrodes 12 and transparent electrodes 16 orthogonal to each other. The passive matrix display device 100 includes a light emitting device array in which a plurality of light emitting devices shown in FIG. 9 are two-dimensionally arranged. In addition, the passive matrix display device 100 includes a plurality of rear electrodes 12 extending parallel a first direction parallel to the surface of the light emitting device array, and a plurality of transparent electrodes 16 extending parallel to a second direction parallel to the surface of the light emitting device array and orthogonal to the first direction. Furthermore, in the passive matrix display device 100, an external voltage is applied between a pair of rear electrode 12 and transparent electrode 16 to drive one light emitting device, and the obtained light emission is extracted from the side of the transparent electrode 16. Moreover, it is possible to implement the display device as a color display device in the same way as in fourth embodiment describe above.

### <Advantageous Effects>

According to this passive matrix display device 100, a display device can be achieved to provide a high light emission luminance, a high luminance efficiency, and high reliability, as in the case of the display device according to fourth embodiment.

### Sixth Embodiment

### Schematic Structure of Light Emitting Device

FIG. 12 is a schematic cross-sectional view of the schematic structure of a light emitting device according to sixth embodiment from the viewpoint perpendicular to a phosphor layer 13. The phosphor layer 13 containing phosphor particles 14 is sandwiched between a rear electrode 12 that is a first electrode and a transparent electrode 16 that is a second electrode. As a support for these layer and electrodes, a substrate 11 is adjacent to the rear electrode 12. The phosphor layer 13 includes phosphor particles 14 and conductive nano particles 23 dispersed in a hole transport material 15 as a medium. Furthermore, conductive nano particles 23 are present among the phosphor particles 14, and the respective phosphor particle 14 form electrical connection through the conductive nano particles 23. A power supply 17 is electrically connected to the rear electrode 12 and the transparent electrode 16. When power is supplied from the power supply 17, a voltage is applied between the rear electrode 12 and the transparent electrode 16. Holes are injected from the rear electrode 12, through the conductive nano particles 23 in the phosphor layer 13, into the phosphor particles 14. On the other hand, electrons are injected from the transparent electrode 16, through the conductive nano particles 23 in the phosphor layer 13, into the phosphor particles 14. The holes and electrons injected into the phosphor particles 14 are recombined to emit light with a wavelength corresponding to the band gap. The emitted light passes through the transparent electrode 16, and is extracted to the outside of the light emitting device 10. In the sixth embodiment, a direct-current power supply is used as the power supply 17.

It is to be noted that the embodiment is not limited to the structure described above, changes can be appropriately made, in such a way that a black electrode is used as the rear electrode 12, a structure is further provided for sealing all or part of the light element 10 with a resin or a ceramic, or a hole injection layer is further provided between the transparent electrode 16 and the phosphor layer 13.

The respective components constituting this light emitting device 10 will be described.

It is to be noted that the substrate is substantially the same as the substrate in the light emitting device according to first embodiment, and description of the substrate will be thus omitted.

### <Electrode>

The electrodes include the rear electrode 12 and the transparent electrode 16. Of the two electrodes, the electrode on the side from which light is extracted is used as the transparent electrode 16. On the other hand, the other is used as the rear electrode 12.

The material of the transparent electrode 16 on the side from which light is extracted may be any material having a light transmitting property so that light generated in the phosphor layer 13 can be extracted, and preferably has a high transmittance, in particular, in a visible light region. Furthermore, the material is preferably a low resistance material, and further, preferably has excellent adhesion with the phosphor layer 13. Furthermore, a material is more preferably capable to be deposited on the phosphor layer 13 at a low temperature so as to prevent the phosphor layer 13 from being thermally deteriorated. Particularly preferred materials of the transparent electrode 16 include, but are not particularly limited to, metal oxides based on an ITO (In₂O₃ doped with SnO₂, which is also referred to as an indium tin oxide), InZnO, ZnO, SnO₂, or the like; metal thin films such as Pt, Au, Pd, Ag, Ni, Cu, Al, Ru, Rh, and Ir; or conductive polymers such as a polyaniline, a polypyrrole, PEDOT/PSS, and a polythiophene. Furthermore, the transparent electrode 16 desirably has a volume resistivity of 1×10⁻³ Ωcm or less, a transmittance of 75% or more for wavelengths from 380 to 780 nm, and a refractive index from 1.85 to 1.95. For example, an ITO can be deposited by a deposition method such as sputtering, electron beam evaporation, or ion plating, for the purpose of improving the transparency or lowering the resistivity. Furthermore, after the deposition, surface treatment such as a plasma treatment may be applied for the purpose of controlling the resistivity. The film thickness of the transparent electrode 16 is determined from the required sheet resistance and visible light transmittance. While the transparent electrode 16 may be directly formed on the phosphor layer 13, the transparent electrode 16 including a transparent conductive film may be formed on a glass substrate and attached so that the transparent conductive film comes in contact with the phosphor layer 13.

The rear electrode 12 on the side from which no light is extracted may be any electrode having electrically conductive property and having excellent adhesion with the substrate 11 and the phosphor layer 13. As preferred examples, for example, metal oxides such as ITO, InZnO, ZnO, and SnO₂, metals such as Pt, Au, Pd, Ag, Ni, Cu, Al, Ru, Rh, Ir, Cr, Mo, W, Ta, Nb, and laminated structures thereof, conductive polymers such as a polyaniline, a polypyrrole, PEDOT [poly(3,4-ethylene dioxythiophene)]/PSS (polyethylene sulfonic acid), or conductive carbon can be used.

The rear electrode 12 may be configured to cover the entire surface of the layer, or may be configured to have a plurality of stripe-shaped electrodes in the layer. Furthermore, the rear electrode 12 and the transparent electrode 16 may be configured to have a plurality of stripe-shaped electrodes, in such a way that each stripe-shaped electrode of the rear electrode 12 and all of the strip-shaped electrodes of the transparent electrode 16 have a skew relationship with each other and that projections of each stripe-shaped electrode of the rear electrode 12 onto the light emitting surface and projections of all of the stripe-shaped electrodes of the rear electrode 16 onto the light emitting surface intersect with each other. In this case, the application of a voltage to the electrodes respectively selected from the respective stripe-shaped electrodes of the rear electrode 12 and the respective striped-shaped electrodes of the transparent electrode 16 allows a display to be configured in such a way that light is emitted in a predetermined position.

### <Phosphor Layer>

The phosphor layer 13 includes the phosphor particles 14 and the conductive nano particles 23 dispersed in the hole transport material 15 as a medium (FIG. 12). Furthermore, the conductive nano particles 23 are present among the phosphor particles 14, and the respective phosphor particle 14 forms electrical connection through the conductive nano particles 23. Holes are injected from the rear electrode 12 through the conductive nano particles 23 into the phosphor particles 14, whereas electrons are injected from the transparent electrode 16 through the conductive nano particles 23 into the phosphor particles 14. The holes and electrons injected into the phosphor particles 14 are recombined to emit light with a wavelength corresponding to the band gap.

### <Phosphor Particle>

As the phosphor particles 14, any material having an optical bandgap being as wide as visible light can be used. Specifically, AlN, GaN, InN, AlP, GaP, InP, AlAs, GaAs, AlSb, and the like which are Group XIII-Group XV compound semiconductors can be used. In particular, Group XIII nitride semiconductors typified by GaN are preferable. Furthermore, mixed crystals thereof (for example, GaInN, etc.) may be used. Moreover, in order to control the conductivity, the material may contain, as a dopant, one or more elements selected from the group consisting of Si, Ge, Sn, C, Be, Zn, Mg, Ge, and Mn.

Furthermore, with a nitride such as InGaN or AlGaN, ZnSe or ZnS, or further ZnS, ZnSe, GaP, CdSe, CdTe, SrS, CaS, or ZnO as a mother body, the mother body can be used as it is, or phosphor particles with the addition of one or more elements selected from Ag, Al, Ga, Cu, Mn, Cl, Tb, and Li can be used. In addition, multicomponent compounds such as ZnSSe and thiogallate based phosphor can be also used.

Furthermore, the multiple compositions in the phosphor particles 14 may have a laminated structure or a segregated structure. The phosphor particles 14 may have a particle diameter in the range of 0.1 μm to 1000 μm, more preferably, in the range of 0.5 μm to 500 μm.

### <Conductive Nano Particle>

The conductive nano particles 23 can use metal material particles such as Ag, Au, Pt, Ni, and Cu, oxide particles such as an indium tin oxide, ZnO, and InZnO, carbon material particles such as carbon nanotubes. The shapes of the conductive nano particles 23 may be any shape such as granular, circular, columnar, acicular, or amorphous. The average particle diameter of the conductive nano particles 23 preferably falls within the range of 1 nm to 200 nm, more preferably within the range of 1 nm to 100 nm. The average particle diameter less than 1 nm results in poor conductivity, decreasing the light emission luminance. On the other hand, the average particle diameter greater than 200 nm increases electrical conduction between the electrodes, while the number of the phosphor particles 14 which are not included in the conductive path is increased, decreasing the light emission luminance and efficiency.

The production of carbon nanotubes is carried out by a method such as a vapor phase synthetic method or plasma method, and depending on the manufacturing conditions, the electrical characteristics, diameters, lengths, and the like of the carbon nanotubes can be arbitrarily varied. In the case of holding a carbon nanotube at the electrode interface on the positive electrode side, it is preferable to use a p-type carbon nanotube as the carbon nanotube. In the case of holding a carbon nanotube at the electrode interface on the negative electrode side, it is preferable to use an n-type carbon nanotube as the carbon nanotube. The p-type carbon nanotube is obtained by doping a carbon nanotube with a Group 5 element such as phosphorus, whereas the n-type carbon nanotube is obtained by doping a carbon nanotube with a Group 3 element such as nitrogen.

### <Hole Transport Material>

Next, the hole transport material 15 as a medium in which the phosphor particles 14 and the conductive nano particles 23 are dispersed will be described. As the hole transport material 15, organic hole transport materials and inorganic hole transport materials are cited. The hole transport material 15 is preferably a material with a high hole mobility.

### <Organic Hole Transport Material>

This organic hole transport material preferably contains components of the following chemical formula 14 and chemical formula 15.

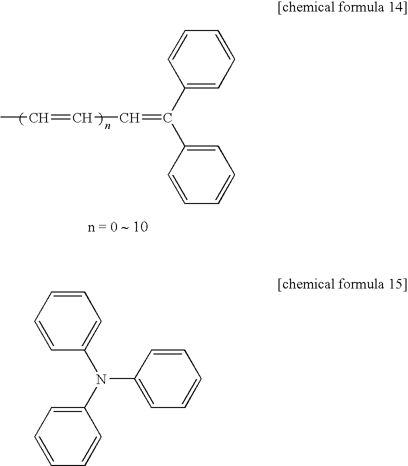

It is believed that the advantageous effect of the organic hole transport material containing the components of the above chemical formula 14 and chemical formula 15 is efficient injection of holes for the phosphor particles 14.

Furthermore, this organic hole transport material may contain any of the following chemical formula 16, chemical formula 17, and chemical formula 18 as a component.

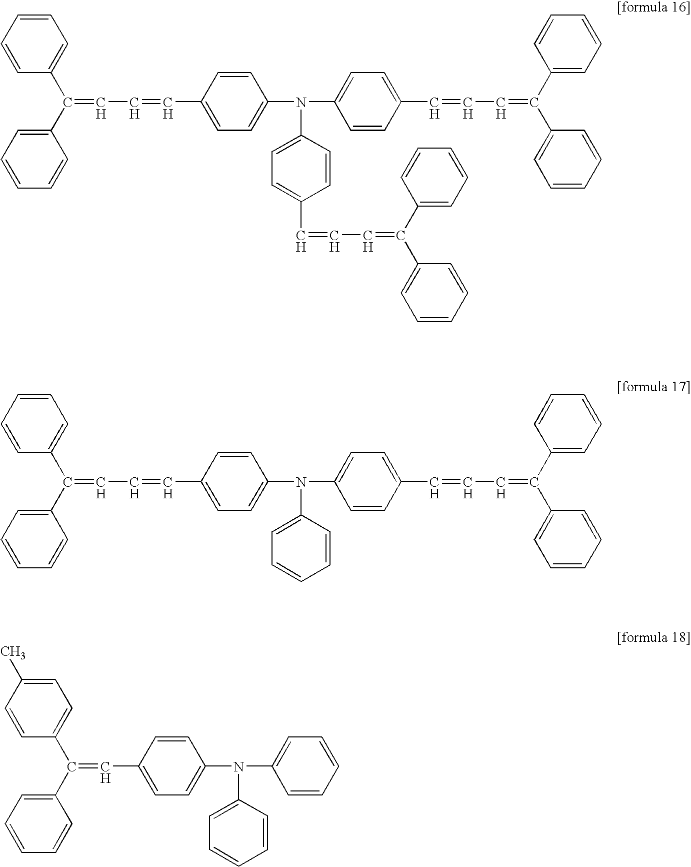

In addition, the main types of organic hole transport materials are low-molecular-weight materials and high-molecular-weight materials. Low-molecular-weight materials having a hole transport property include diamine derivatives used by Tang et al., such as N,N′-bis(3-methylphenyl)-N,N′-diphenylbenzidine (TPD) and N,N′-bis(α-naphthyl)-N,N′-diphenylbenzidine (NPD), in particular, diamine derivatives having a Q1-G-Q2 structure, disclosed in Japanese Patent No. 2037475, where Q1 and Q2 are separately a group having a nitrogen atom and at least three carbon chains (at least one of the carbon chains comes from an aromatic group), and G is a linking group including a cycloalkylene group, an arylene group, an alkylene group or a carbon-carbon bond. Alternatively, the organic hole transport material may be polymers (oligomers) including these structural units. These polymers include polymers having a spiro structure or a dendrimer structure. Furthermore, the form in which molecules of a low-molecular-weight hole transport material are dispersed in a non-conductive polymer is likewise available. Specific examples of the molecular dispersion system include an example in which molecules of TPD are dispersed in high concentration in a polycarbonate, with the hole mobility on the order of 10⁻⁴ to 10⁻⁵ cm²/Vs.

On the other hand, high-molecular-weight materials having a hole transport property include π-conjugated polymers and σ-conjugated polymers, and for example, a high-molecular-weight material in which an arylamine compound is incorporated. Specifically, the high-molecular-weight materials include, but are not limited to, poly-para-phenylenevinylene derivatives (PPV derivatives), polythiophenes derivatives (PAT derivatives), polyparaphenylene derivatives (PPP derivatives), polyalkylphenylene (PDAF), polyacetylene derivatives (PA derivatives), and polysilane derivatives (PS derivatives). Furthermore, the high-molecular-weight materials may be polymers with a low-molecular-weight and a hole-transport molecular property incorporated into their molecular chains, and specific examples of the polymers includes polymethacrylamides with an aromatic amine in their side chains (PTPAMMA, PTPDMA) and polyethers with an aromatic amine in their main chains (TPDPES, TPDPEK). Above all, as a particularly preferred example, above all, poly-N-vinylcarbazole (PVK) exhibits an extremely high hole mobility of 10⁻⁶ cm²/Vs. Other specific examples include PEDOT/PSS and polymethylphenylsilane (PMPS).

Moreover, multiple types of the hole transport material mentioned above may be mixed and used. Furthermore, the organic hole transport material may contain a crosslinkable or polymerizable material cross-linked or polymerized by light or heat.

### <Inorganic Hole Transport Material>

Inorganic hole transport materials will be described. The inorganic hole transport material may be any material being transparent or semi-transparent and having p-type conductivity. Preferred inorganic hole transport materials include metalloid semiconductors such as Si, Ge, SiC, Se, SeTe, and As₂Se₃; binary compounds such as ZnS, ZnSe, CdS, ZnO, and CuI; chalcopyrite semiconductors such as CuGaS₂, CuGaSe₂, and CuInSe₂, and further mixed crystals of these semiconductors; and oxide semiconductors such as CuAlO₂ and CuGaO₂, and further mixed crystals of these semiconductors. Moreover, a dopant may be added to these materials, in order to control the conductivity.

### <Method for Manufacturing Phosphor Layer>

Next, a method for manufacturing the phosphor layer 13 will be described.

(a) The phosphor particles 14 and the conductive nano particles 23 are mixed and stirred in the hole transport material 15 with any solvent and the like added to prepare a light emitting paste.

(b) Next, the light emitting paste is deposited on the rear electrode 12 provided on the substrate 11, and the solvent and the like are volatilized by drying to form the phosphor layer 13. As the application method in this case, inkjet, dipping, spin coating, screen printing, bar-code, and other various types of application methods can be used. In addition, the application method can be appropriately changed to spray coating, electrostatic painting without the use of a solvent and with the use of a powder material, fluidized bed coating, aerosol deposition, etc. Furthermore, other deposition methods for the organic hole transport material includes vacuum deposition, etc., and it is also possible to form the phosphor layer by the combination of these methods.

A feature of the light emitting device according to sixth embodiment of the present invention is that the phosphor layer 13 includes the phosphor particles 14 and the conductive nano particles 23 dispersed in the hole transport material 15 as a medium, in which the conductive nano particles 23 are present among the phosphor particles 14. Furthermore, the conductive nano particles 23 present among the phosphor particles 14 can reduce the contact resistance among the phosphor particles 14 to improve the hole injection property. In addition, the use of the organic hole transport material 15 as the medium of the phosphor layer 13 makes it easier to enlarge the light emitting device, and allows leakage between the electrode through a path among the particles to be reduced. Therefore, a light emitting device having a higher luminance, a higher efficiency, and high reliability can be achieved.

### <Advantageous Effects>

The light emitting device according to the present invention provides light emission with a higher luminance and a higher efficiency than light emitting devices using conventional compound semiconductor particles or the like.

### Example 2

Phosphor particles mainly containing GaN and inorganic conductive nano fine particles (Cu₂S fine particles) were mixed, stirred, and dispersed in an organic hole transport material (a tetraphenylbutadiene derivative). Then, the obtained paste is sandwiched along with spacers between a pair of glass substrates ITO electrodes to prepare a device for EL confirmation. When a direct current voltage was applied to this device for EL confirmation to evaluate the device, the device exhibited a light emission luminance of 180 cd/m² at 12V. This result was superior to the following comparative examples.

### Comparative Example 1

Phosphor particles mainly containing GaN were dispersed in an insulating silicon oil, and sandwiched along with spacers by glass substrates with ITO electrodes to prepare a device for EL confirmation. When a direct current voltage was applied to this device for evaluation of the device, the device exhibited light emission at 50 V (with a light emission luminance less than 1 cd/m²).

### Comparative Example 2

Phosphor particles mainly containing GaN were dispersed in an organic hole transport material (a tetraphenylbutadiene derivative), and sandwiched along with spacers by glass substrates with ITO electrodes to prepare a device for EL confirmation. When a direct current voltage was applied to this device for evaluation of the device, the device exhibited a light emission luminance less than 15 cd/m² at 20 V.

The light emitting devices and display devices according to the present invention provide light emissions with a high light emission luminance and with a high luminous efficiency and provide reliability for long periods of time. In particular, the light emitting devices and display devices are useful as display devices such as televisions and a variety of light sources for use in communication, illumination, etc.

1. A light-emitting device comprising:
a first electrode and a second electrode arranged facing each other, at least one of the electrodes being transparent or semi-transparent; and
a phosphor layer provided as being sandwiched between the first electrode and the second electrode, wherein conductive nano particles and phosphor particles are dispersed in a medium including a hole-transporting material.

2. A light-emitting device comprising:
a first electrode and a second electrode arranged facing each other, at least one of the electrodes being transparent or semi-transparent; and
a phosphor layer provided as being sandwiched between the first electrode and the second electrode, the phosphor layer including a phosphor particle powder containing phosphor particles, the phosphor particle having at least surface covered with a coating layer, the coating layer including a hole transport material and conductive nano particles dispersed in the hole transport material.

3. The light-emitting device according to claim 2, wherein the phosphor layer includes binder among the phosphor particles.

4. The light-emitting device according to claim 2, wherein the conductive nano particles are interspersed among the respective phosphor particles, the respective phosphor particles form an electrical connection through the conductive nano particles.

5. The light-emitting device according to claim 4, wherein the conductive nano particles include at least one metal fine particle selected from the group constituting of Ag, Au, Pt, Ni, and Cu.

6. The light-emitting device according to claim 4, wherein the conductive nano particles include at least one oxide fine particle selected from the group constituting of an indium tin oxide, ZnO, and InZnO.

7. The light-emitting device according to claim 4, wherein the conductive nano particles include at least one carbon substance fine particle selected from the group of fullerene and a carbon nanotube.

8. The light-emitting device according to claim 4, wherein the conductive nano particles have an average particle diameter within the range of 1 to 200 nm.

9. The light-emitting device according to claim 1, wherein the hole transport material includes an organic hole transport material including an organic matter.

10. The light emitting device according to claim 9, wherein the organic hole transport material contains components of the following chemical formula 1 and chemical formula 2.

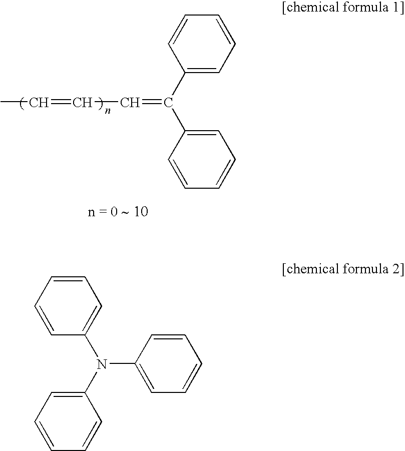

11. The light emitting device according to claim 10, wherein the organic hole transport material further includes at least one component of the group constituting of the following chemical formula 3, chemical formula 4, and chemical formula 5.

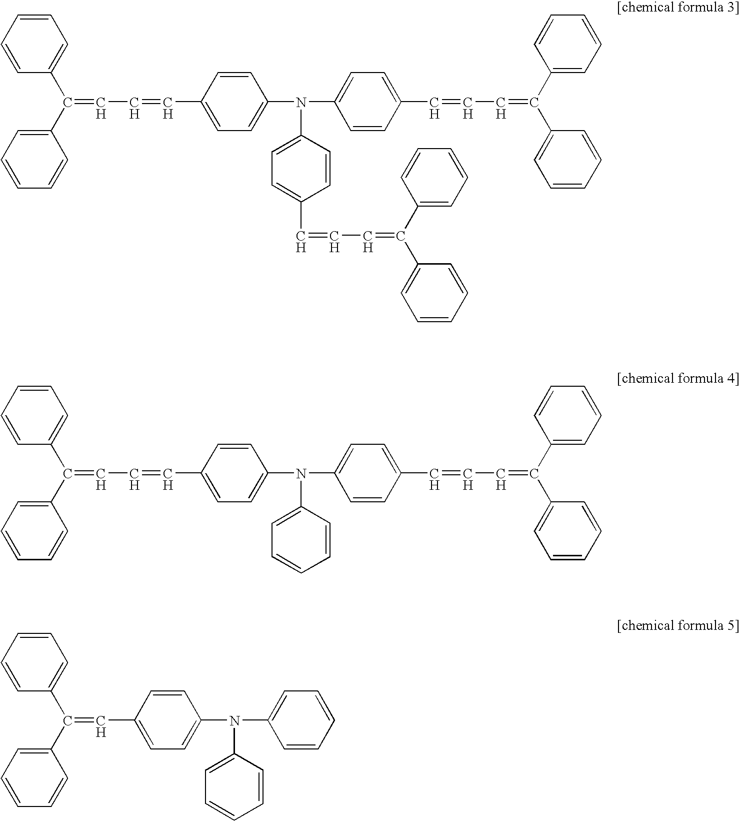

12. The light emitting device according to claim 10, wherein the organic hole transport material further includes at least one component of the group constituting of the following chemical formula 6, chemical formula 7, and chemical formula 8.

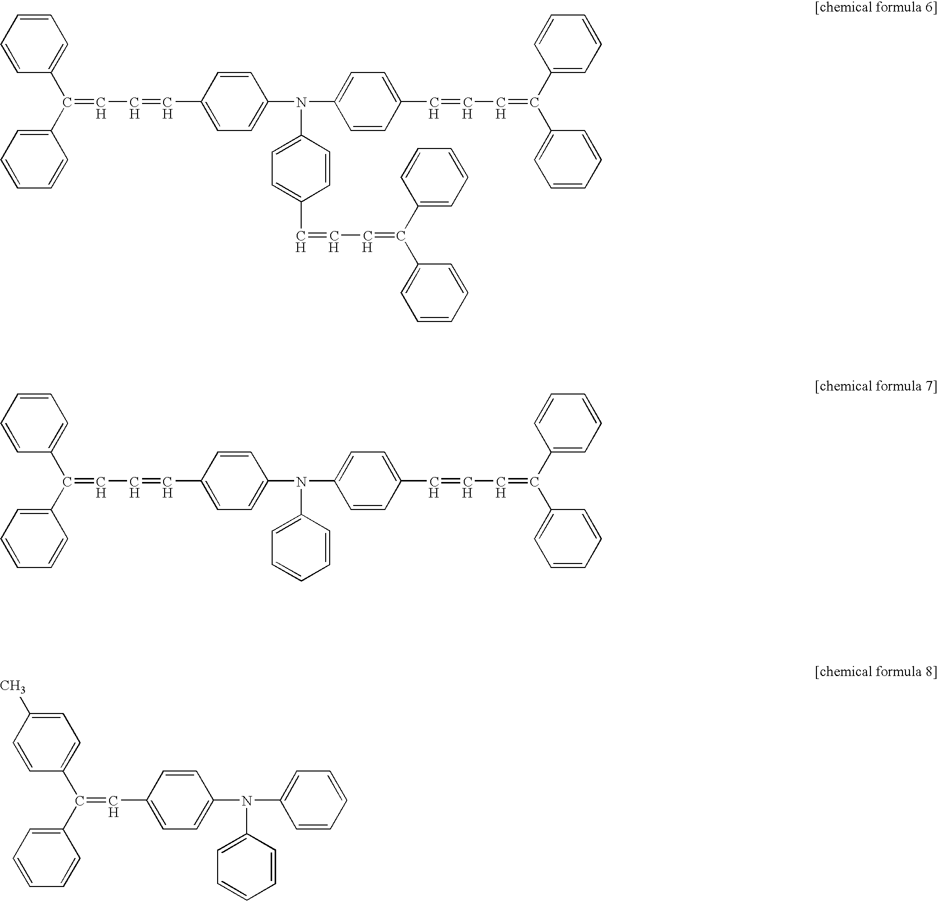

13. The light emitting device according to claim 1, wherein the hole transport material includes an inorganic hole transport material including an inorganic matter.

14. The light emitting device according to claim 1, wherein the phosphor particles include a particle including a Group 13-Group 15 compound semiconductor.

15. The light emitting device according to claim 1, wherein the phosphor particles include at least one light emitting material selected from the group of a nitride, a sulfide, a selenide, and an oxide.

16. The light emitting device according to claim 14, wherein the phosphor particles are nitride semiconductor particles including at least one element of Ga, Al, and In.

17. The light emitting device according to claim 16, wherein the phosphor particles are phosphor particles including GaN.

18. The light emitting device according to claim 1, wherein the phosphor particles have an average particle diameter within the range of 0.1 μm to 1000 μm.

19. The light emitting device according to claim 1, wherein the conductive nano particles are selected from the group of metal material particles such as Ag, Au, Pt, Ni, and Cu.

20. The light-emitting device according to claim 1, wherein the conductive nano particles are selected from oxide particles such as an indium tin oxide, ZnO, and InZnO.

21. The light-emitting device according to claim 1, wherein the conductive nano particles are selected from the group of carbon material particles such as a carbon nanotube.

22. The light-emitting device according to claim 1, wherein the conductive nano particles have an average particle diameter or an average length within the range of 1 to 200 nm.

23. The light emitting device according to claim 1, further comprising a hole injection layer sandwiched between the first electrode and the phosphor layer.

24. The light emitting device according to claim 1, further comprising a support substrate facing the first electrode or the second electrode for support.

25. The light emitting device according to claim 24, wherein the support substrate is a glass substrate or a resin substrate.

26. The light emitting device according to claim 25, further comprising a thin film transistors connected to the first electrode or the second electrode.

27. A display device comprising:
a light emitting device array in which the light emitting device according to claim 26 is two-dimensionally arranged in plural;
a plurality of x electrodes extending parallel to each other in a first direction parallel to a surface of the light emitting device array; and
a plurality of y electrodes extending parallel to a second direction parallel to the surface of the light emitting device array and orthogonal to the first direction,
wherein the thin film transistors of the light emitting device array are each connected to the x electrodes and the y electrodes.

28. A display device comprising:
a light emitting device array in which the light emitting device according to claim 26 is two-dimensionally arranged in plural;
a plurality of x electrodes extending parallel to each other in a first direction parallel to a surface of the light emitting device array; and
a plurality of y electrodes extending parallel to a second direction parallel to the surface of the light emitting device array and orthogonal to the first direction.

29. The display device according to claim 27, further comprising a color conversion layer anteriorly in a direction of light emission extraction.
